(19) United States
(12) Patent Application Publication
(10) Pub. No.: US 2025/0390000 A1
(43) Pub. Date: Dec. 25, 2025

(54) LIGHT TRANSMISSION CONTROL MEMBER AND DISPLAY DEVICE COMPRISING SAME

(71) Applicant: LG INNOTEK CO., LTD., Seoul (KR)

(72) Inventors: Byung Sook KIM, Seoul (KR); In Hae LEE, Seoul (KR)

(21) Appl. No.: 18/879,606

(22) PCT Filed: Apr. 3, 2023
(86) PCT No.: PCT/KR2023/004447

§ 371 Date: Dec. 27, 2024

(30) Foreign Application Priority Data
Jun. 28, 2022 (KR) 10-2022-0078783

(51) Int. Cl. G02F 1/16757; G02F 1/167; G02F 1/1676

(52) U.S. Cl. CPC G02F 1/16757; G02F 1/167; G02F 1/1676

(57) ABSTRACT

A light transmission control member according to an embodiment includes a first substrate; a first electrode disposed on the first substrate; a second substrate disposed on the first substrate; a second electrode disposed under the second substrate; a light conversion part disposed between the first electrode and the second electrode, wherein the light conversion part includes a receiving part and a capsule part disposed inside the receiving part, and a plurality of capsule parts are disposed on the first electrode.

### TECHNICAL FIELD

An embodiment relates to a light transmission control member and a display device including the same.

### BACKGROUND ART

A light transmission control member is a light blocking film in which a transmittance of light emitted a light source changes. The light transmission control member can be attached to a front of a display panel, which is a display device used in a mobile phone, a laptop, a tablet PC, a vehicle navigation system, or a vehicle touch screen. That is, the light transmission control member is attached to the display panel. In addition, the light transmission control member adjusts an angle of light emission. Accordingly, the display panel can be used for privacy purposes.

In addition, the light transmission control member is used for a window of a vehicle or a window of a building. Accordingly, it partially blocks external light to prevent glare. Alternatively, it prevents an inside from being seen from an outside. That is, the light transmission control member is attached to a window of the vehicle or a window of the building. Accordingly, the window of the vehicle or the window of the building can be used for privacy purposes by adjusting the light transmittance.

The light transmission control member includes a light conversion part. A light conversion material including light conversion particles is disposed inside the light conversion part. The light conversion part is switched into a light transmitting part and a light blocking part by dispersion and agglomeration of the light conversion particles.

### DISCLOSURE

### Technical Problem

The embodiment provides a light transmission control member that implements various operations.

The embodiment provides a light transmission control member with a reduced light transmittance while operating as a light blocking part.

### Technical Solution

An light transmission control member according to an embodiment includes a first substrate; a first electrode disposed on the first substrate; a second substrate disposed on the first substrate; a second electrode disposed under the second substrate; a light conversion part disposed between the first electrode and the second electrode, wherein the light conversion part includes a receiving part and a capsule part disposed inside the receiving part, and a plurality of capsule parts are disposed on the first electrode.

### Advantageous Effects

A light transmission control member according to the embodiment includes a first electrode. In addition, a plurality of capsule parts are disposed on one first electrode. Accordingly, a light transmittance of the light transmission control member changes on a front surface of the light transmission control member by a single voltage application.

Accordingly, an user can conveniently use the light transmission control member. In addition, a power consumption required to drive the light transmission control member is reduced.

In addition, the first electrode includes a plurality of pattern electrodes. In addition, a plurality of capsule parts are disposed on each pattern electrode.

In addition, the pattern electrodes are individually driven. Accordingly, the light transmittance of the light transmission control member changes in various ways depending on the individual driving method of the pattern electrodes.

Accordingly, the user can use the light transmission control member in various environments. In addition, the user can use the light transmission control member for various purposes. For example, the light transmission control member can be used for various purposes by displaying symbols, letters, numbers, etc. on the light transmission control member.

In addition, the capsule part includes a plurality of capsule parts of different sizes. Alternatively, the plurality of capsule parts are disposed in two or more layers. Accordingly, when the light transmission control member is used as a light blocking part, the light transmittance is reduced. Accordingly, the user's visibility is improved.

### DESCRIPTION OF DRAWINGS

FIG. 1 is a perspective view of a light transmission control member according to an embodiment.

FIG. 2 and FIG. 3 are cross-sectional views taken along region A-A′ of FIG. 1.

FIG. 4 and FIG. 5 are top views of a light conversion part of a light transmission control member according to an embodiment.

FIG. 6 to FIG. 9 are another cross-sectional views of a light transmission control member according to an embodiment.

FIG. 10 is another top view of a light conversion part of a light transmission control member according to an embodiment.

FIG. 11 is another top view of a light conversion part of a light transmission control member according to an embodiment.

FIG. 12 is another cross-sectional view of a light transmission control member according to an embodiment.

FIG. 13 is another cross-sectional view of a light transmission control member according to an embodiment.

FIG. 14 is a cross-sectional view taken along region B-B′ of FIG. 1.

FIG. 15 is a drawing for explaining a cutting process of a light transmission control member according to an embodiment.

FIG. 16 and FIG. 17 are drawings showing cross-sectional views of a display device to which a light transmission control member according to an embodiment is applied.

FIG. 18 to FIG. 22 are drawings for explaining one embodiment of a display device to which a light transmission control member according to an embodiment is applied.

### MODE FOR INVENTION

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and redisposed.

In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art.

In addition, the terms used in the embodiments of the present disclosure are for describing the embodiments and are not intended to limit the present disclosure. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

Hereinafter, a light transmission control member according to an embodiment will be described with reference to the drawings.

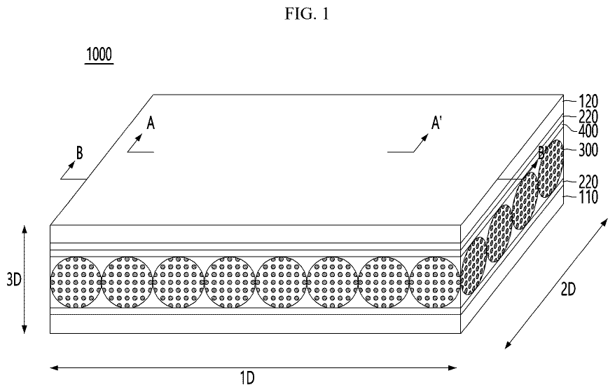

Referring to FIGS. 1 to 5, a light transmission control member 1000 according to an embodiment includes a first substrate 110, a second substrate 120, a first electrode 210, a second electrode 220, and a light conversion part 300. In addition, the light transmission control member 1000 may further include an adhesive layer 400.

The first substrate 110 and the second substrate 120 support the light conversion part 300. The first substrate 110 and the second substrate 120 may be rigid or flexible.

In addition, the first substrate 110 may be transparent. For example, the first substrate 110 may include a transparent substrate capable of transmitting light.

The first substrate 110 and the second substrate 120 may include glass, plastic, or a flexible polymer film. For example, the flexible polymer film may include any one of polyethylene terephthalate (PET), polycarbonate (PC), acrylonitrile-butadiene-styrene copolymer (ABS), polymethyl methacrylate (PMMA), polyethylene naphthalate (PEN), polyether sulfone (PES), cyclic olefin copolymer (COC), triacetylcellulose (TAC) film, polyvinyl alcohol (PVA) film, polyimide (PI) film, and polystyrene (PS). This is only an example and is not necessarily limited thereto.

In addition, the first substrate 110 and the second substrate 120 may be flexible substrates having flexible characteristics.

In addition, the first substrate 110 and the second substrate 120 may be curved or bent substrates. Accordingly, the light transmission control member may also have flexible, curved or bent characteristics. Accordingly, the light transmission control member according to the embodiment may be changed into various designs.

The first substrate 110 and the second substrate 120 may be defined in a first direction 1D, a second direction 2D, and a third direction 3D. The first direction 1D, the second direction 2D, and the third direction 3D are different directions.

The first direction ID and the second direction 2D may correspond to a longitudinal or width direction of the first substrate 110 and the second substrate 120. In addition, the third direction 3D may correspond to a thickness direction of the first substrate 110 and the second substrate 120.

For example, the first direction 1D may be defined as a longitudinal direction of the first substrate 110 and the second substrate 120. The second direction 2D may be defined as a width direction of the first substrate 110 and the second substrate 120. The third direction 3D may be defined as a thickness direction of the first substrate 110 and the second substrate 120. Alternatively, the first direction 1D may be defined as a width direction of the first substrate 110 and the second substrate 120. The second direction 2D may be defined as a longitudinal direction of the first substrate 110 and the second substrate 120. The third direction 3D may be defined as a thickness direction of the first substrate 110 and the second substrate 120.

Hereinafter, for convenience of explanation, the first direction ID is defined as the longitudinal direction of the first substrate 110 and the second substrate 120. In addition, the second direction 2D is defined as the width direction of the first substrate 110 and the second substrate 120. In addition, the third direction 3D is defined as the thickness direction of the first substrate 110 and the second substrate 120.

The first substrate 110 and the second substrate 120 have a thickness within a set range. For example, the first substrate 110 may have a thickness of 25 um to 150 um.

The first electrode 210 and the second electrode 220 are respectively disposed on one surface of the first substrate 120 and one surface of the second substrate 120. In detail, the first electrode 210 is disposed on an upper surface of the first substrate 110. The second electrode 220 is disposed on a lower surface of the second substrate 120.

The first electrode 210 and the second electrode 220 may include a conductive material. For example, at least one of the first electrode 210 and the second electrode 220 may include a transparent conductive material. For example, at least one of the first electrode 210 and the second electrode 220 may include a conductive material having a light transmittance of about 80% or more. For example, at least one of the first electrode 210 and the second electrode 220 may include indium tin oxide, indium zinc oxide, copper oxide, tin oxide, zinc oxide, or titanium oxide.

The first electrode 210 and the second electrode 220 are formed with a thickness within a set range. For example, the second electrode 200 may have a thickness of about 10 nm to about 300 nm.

Alternatively, at least one of the first electrode 210 and the second electrode 220 may include various metals to implement low resistance. For example, at least one of the first electrode 210 and the second electrode 220 may include chromium (Cr), nickel (Ni), copper (Cu), aluminum (Al), silver (Ag), molybdenum (Mo), gold (Au), titanium (Ti), or an alloy thereof.

At least one of the first electrode 210 and the second electrode 220 may be disposed on an entire surface of one surface of the first substrate 110 and an entire surface of one surface of the second substrate 120. In detail, at least one of the first electrode 210 and the second electrode 220 may be disposed as a surface electrode.

Alternatively, at least one of the first electrode 210 and the second electrode 220 may be disposed as a plurality of pattern electrodes on one surface of the first substrate 110 and one surface of the second substrate 120.

In addition, at least one of the first electrode 210 and the second electrode 220 may be disposed in a mesh shape including an opening. Accordingly, even if at least one of the first electrode 210 and the second electrode 220 includes a metal, the electrode is not visible from an outside, and thus, visibility may be improved. In addition, since a light transmittance increases by the opening, a brightness of the light transmission control member may be improved.

The light conversion part 300 is disposed between the first substrate 110 and the second substrate 120. In detail, the light conversion part 300 is disposed between the first electrode 210 and the second electrode 220.

An adhesive layer 400 is disposed between the light conversion part 300 and the second electrode 220. The light conversion part 300 and the second electrode 200 can be adhered by the adhesive layer 400.

The adhesive layer 400 can include a light-transmitting material. For example, the adhesive layer 400 can include an optical clear adhesive. In addition, the adhesive layer 400 can have a thickness within a set range. For example, the adhesive layer 400 can have a thickness of 50 um or less. If the thickness of the adhesive layer 400 exceeds 50 um, the overall thickness of the light transmission control member may increase.

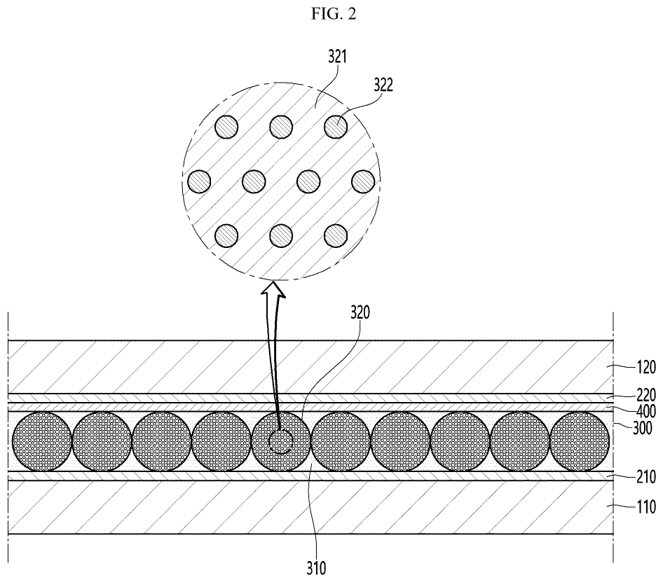

Referring to FIGS. 2 to 5, the light conversion part 300 includes a receiving part 310 and a capsule part 320.

The receiving part 310 is defined as a region where the capsule part 320 is disposed. The capsule part 320 is disposed inside the receiving part 310. The receiving part 310 is disposed to surround the capsule part 320.

The receiving part 310 may include a transparent material. The receiving part 310 may include a material through which light is transmitted.

The receiving part 310 is formed in a set thickness range. In detail, a thickness of the receiving part 310 may be 10 um or more. In more detail, the thickness of the receiving part 310 may be 10 um to 60 um. In more detail, the thickness of the receiving part 310 may be 20 um to 50 um. In more detail, the thickness of the receiving part 310 may be 30 um to 40 um.

If the thickness of the receiving part 310 is less than 10 um, the capsule part 320 is not disposed in a sufficient amount inside the receiving part 310. Accordingly, light blocking characteristic of the light transmission control member is reduced.

In addition, if the thickness of the receiving part 310 exceeds 60 um, a size of the capsule part 320 disposed inside the receiving part 310 increases. Accordingly, a driving power of the light transmission control member increases.

The capsule part 320 is disposed inside the receiving part 310. In detail, the capsule part 320 may be disposed inside the receiving part 310 to be spaced apart each other. Alternatively, the capsule part 320 may be disposed in contact with the inside of the receiving part 310.

The capsule part 320 includes a dispersion 321 and light conversion particles 322 dispersed inside the dispersion 321. In detail, a plurality of light conversion particles 322 are dispersed inside the dispersion 321. One capsule part 320 may be defined as a plurality of light conversion particles 322 dispersed and encapsulated inside the dispersion 321.

The dispersion 321 includes a material capable dispersing the light conversion particles 322. The dispersion 321 may include a transparent material. The dispersion 321 may include a non-polar solvent. In addition, the dispersion 321 may include a material capable transmitting light. For example, the dispersion 321 may include at least one of a halocarbon oil, a paraffin oil, and an isopropyl alcohol.

The light conversion particle 322 is disposed in the dispersion 321. In detail, a plurality of light conversion particles 322 are disposed in a dispersed or aggregated manner in the dispersion 321.

The light conversion particle 322 includes a material capable absorbing light. That is, the light conversion particle 322 may be a light absorbing particle. The light conversion particle 322 may have a color. For example, the light conversion particle 322 may have a black color. As an example, the light conversion particle 322 may include a carbon black particle.

A surface of the light conversion particle 322 may be charged. Accordingly, the light conversion particle 322 may have a polarity. For example, the surface of the light conversion particle 322 can be charged with a negative charge. Accordingly, when a voltage is applied to the light transmission control member, the light conversion particle 322 disposed inside the dispersion 321 moves in one direction.

A light transmittance of the light conversion part 300 changes by the capsule part 320. In detail, the light conversion part 300 switches into a light blocking part and a light transmitting part by the capsule part 320. That is, a light transmittance of the light conversion part 300 changes by dispersion or aggregation of the light conversion particle 322.

For example, the light transmitting member according to the embodiment can be applied with a voltage in an off state. As a result, the light transmission control member is switched from a first mode to a second mode. In addition, the light transmission control member is switched from a second mode to a first mode.

In detail, in the first mode, the light conversion part 300 becomes a light blocking part. Accordingly, the light transmission control member blocks the transmission of light. Accordingly, a display screen is not visible to an outside user. In addition, the light transmission is blocked from a window of a vehicle or a window of a building. Accordingly, a blind mode can be operated. That is, the first mode can be a light blocking mode or a blind mode.

In addition, in the second mode, the light conversion part 300 becomes a light transmitting part. Accordingly, the light transmission control member transmits light. Accordingly, the display screen is visible to an outside user. Accordingly, the user can use the light transmission control member in a public mode. In addition, light is transmitted from a window of a vehicle or a window of a building. Accordingly, a light mode can be operated. That is, the second mode can be a public mode or a light mode.

The light conversion part 300 switching from a light blocking part to a light transmitting part can be implemented by a movement of the light conversion particle 322 of the capsule part 320. That is, the light conversion particle 322 has an electric charge on its surface. When a voltage is applied, the light conversion particle 322 moves toward the first electrode 210.

For example, when a voltage is not applied to the light transmission control member from an outside, the light conversion particle 322 of the capsule part 320 is uniformly dispersed in the dispersion 321. Accordingly, the capsule part 320 blocks light by the light conversion particle 322. Accordingly, in the first mode, the capsule part 320 is driven as a light blocking part.

In addition, when a voltage is applied to the light transmission control member from an outside, the light conversion particle 322 moves. For example, when a positive voltage is applied to the first electrode 210 and a negative voltage is applied to the second electrode 220, the light conversion particle 322 charged with a negative charge moves toward the first electrode 210.

For example, when a voltage is applied to the first electrode 210 and/or the second electrode 220, an electric field is formed inside the capsule part 320. In addition, the light conversion particle 322 charged with a negative charge moves toward the first electrode 210 to which a positive voltage is applied using the dispersion 321 as a medium.

For example, referring to FIGS. 2 and 4, in an initial mode or the first mode in which no voltage is applied, the light conversion particle 322 is uniformly dispersed in the dispersion 321. Accordingly, light incident on the light conversion part 300 is transmitted only in a region where the capsule part 320 is not disposed. Accordingly, the light transmittance of the light transmission control member decreases. Accordingly, the light conversion part 300 is driven as a light blocking part. For example, the light transmittance of the initial mode and the first mode may be 20% or less.

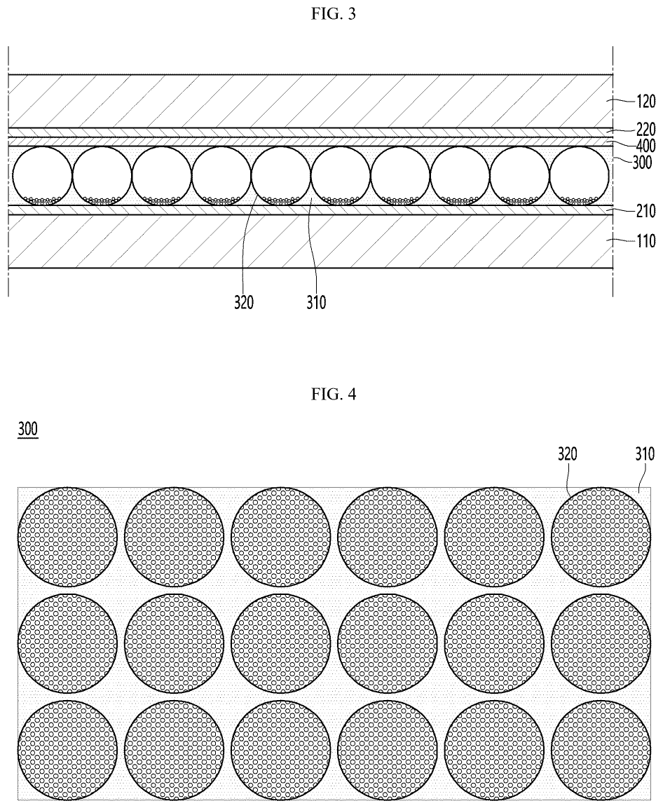

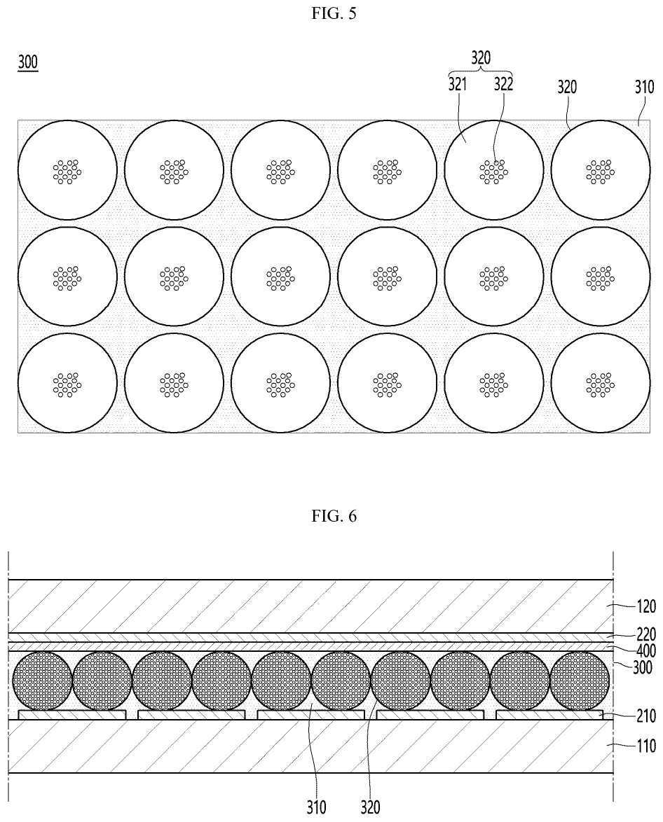

In addition, referring to FIGS. 3 and 5, in the second mode in which a voltage is applied, the light conversion particle 322 moves toward the first electrode 210. Accordingly, the light incident on the light conversion part 300 is transmitted in a region where the capsule part 320 is not disposed and a region where the light conversion particle 322 of the capsule part 320 is not disposed. Accordingly, the light transmittance of the light transmission control member increases. Accordingly, the light conversion part 300 is driven as a light transmitting part. For example, the light transmittance of the second mode may be 80% or more.

Accordingly, the light transmission control member according to the embodiment is driven in two modes depending on an user's surrounding environment, etc.

For example, a display screen can be driven in a privacy mode or a light blocking mode depending on the user's environment. Alternatively, the user can drive the window of a vehicle or a window of a building in a blind mode or a light mode.

Therefore, the light transmission control member according to the embodiment can be driven in two modes depending on the user's needs. Accordingly, the light transmitting member can be used in various modes depending on the user's environment.

Referring to FIGS. 2 and 3, a plurality of capsule parts 320 are disposed on the first electrode 210. The first electrode 210 is disposed as a single surface electrode. In detail, 100 or more capsule parts 320 may be disposed on the first electrode 210. In more detail, 1000 or more capsule parts 320 may be disposed on the first electrode 210. In more detail, 10000 or more capsule parts 320 may be disposed on the first electrode 210.

Accordingly, the plurality of capsule parts 320 disposed on the first electrode 210 may all be driven in a same manner by applying the voltage. That is, when the voltage is applied to the first electrode 210, all light conversion particles 322 of the plurality of capsule parts 320 disposed on the first electrode 210 can move toward the first electrode 210. That is, all light conversion particles 322 of the plurality of capsule parts 320 move with one drive. Therefore, the light transmission control member can be easily driven while reducing power loss.

Meanwhile, referring to FIGS. 6 to 8, at least one of the first electrode 210 and the second electrode 220 may include a pattern electrode.

Referring to FIG. 6, the first electrode 210 is disposed as a pattern electrode. The second electrode 220 is disposed as a surface electrode.

The first electrode 210 includes a plurality of pattern electrodes. In detail, the plurality of pattern electrodes are spaced apart from each other.

The capsule part 320 is disposed on the pattern electrode. In detail, a plurality of capsule parts 320 are disposed on one pattern electrode. In more detail, 100 or more capsule parts 320 can be disposed on one pattern electrode. In more detail, 1000 or more capsule parts 320 can be disposed on one pattern electrode. In more detail, 10000 or more capsule parts 320 can be disposed on one pattern electrode.

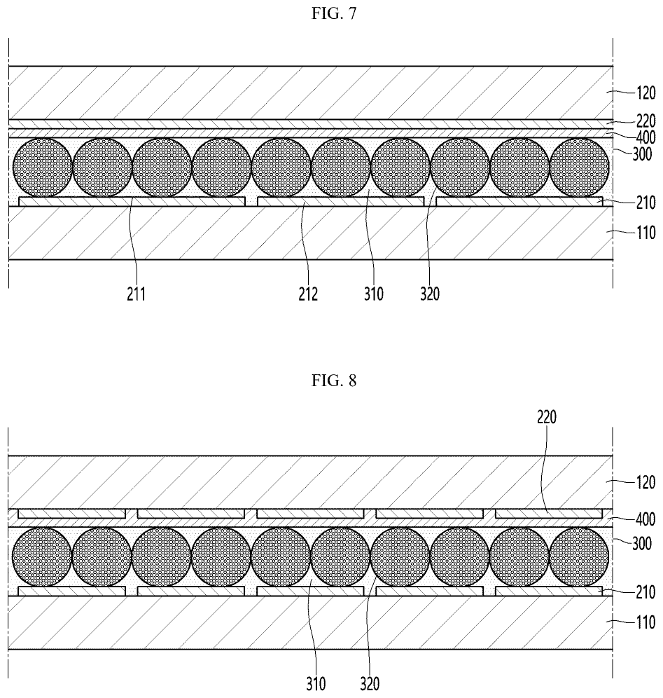

Referring to FIG. 7, the first electrode 210 is disposed as a pattern electrode. The second electrode 220 is disposed as a surface electrode.

The first electrode 210 includes a plurality of pattern electrodes. In detail, the pattern electrode includes a plurality of pattern electrodes 211, 212, and 213 spaced apart from each other. For example, the pattern electrode may include a first pattern electrode 211, a second pattern electrode 212, and a third pattern electrode 213 spaced apart from each other.

The capsule part 320 is disposed on the pattern electrodes 211, 212, and 213. In detail, a plurality of capsule parts 320 are disposed on each of the first pattern electrode 211, the second pattern electrode 212, and the third pattern electrode 213. More specifically, 100 or more capsule parts 320 may be disposed on each of the first pattern electrode 211, the second pattern electrode 212, and the third pattern electrode 213. In more detail, 1,000 or more capsule parts 320 may be disposed on each of the first pattern electrode 211, the second pattern electrode 212, and the third pattern electrode 213. In more detail, 10,000 or more capsule parts 320 may be disposed on each of the first pattern electrode 211, the second pattern electrode 212, and the third pattern electrode 213.

In addition, the first pattern electrode 211, the second pattern electrode 212, and the third pattern electrode 213 may be formed with different widths. In addition, the capsule parts 320 disposed on the first pattern electrode 211, the second pattern electrode 212, and the third pattern electrode 213 may be disposed with different numbers. For example, a number of the capsule parts 320 disposed on the first pattern electrode 211 may be greater than a number of the capsule parts 320 disposed on the second pattern electrode 212 and the third pattern electrode 213. That is, a width of the first pattern electrode 211 may be greater than widths of the second pattern electrode 212 and the third pattern electrode 213. In addition, the number of the capsule parts 320 disposed on the first pattern electrode 211 may be greater than the number of capsule parts 320 disposed on the second pattern electrode 212 and the third pattern electrode 213.

Referring to FIG. 8, the first electrode 210 is disposed as a pattern electrode. The second electrode 220 is disposed as a pattern electrode. That is, both the first electrode 210 and the second electrode 220 are disposed as pattern electrodes.

The first electrode 210 includes a plurality of pattern electrodes. The plurality of pattern electrodes are spaced apart from each other.

In addition, the second electrode 220 includes a plurality of pattern electrodes. The plurality of pattern electrodes are spaced apart from each other.

As shown in FIGS. 6 to 8, since at least one of the first electrode 210 and the second electrode 220 is disposed as a pattern electrode, the light transmission control member can be individually driven by each pattern electrode.

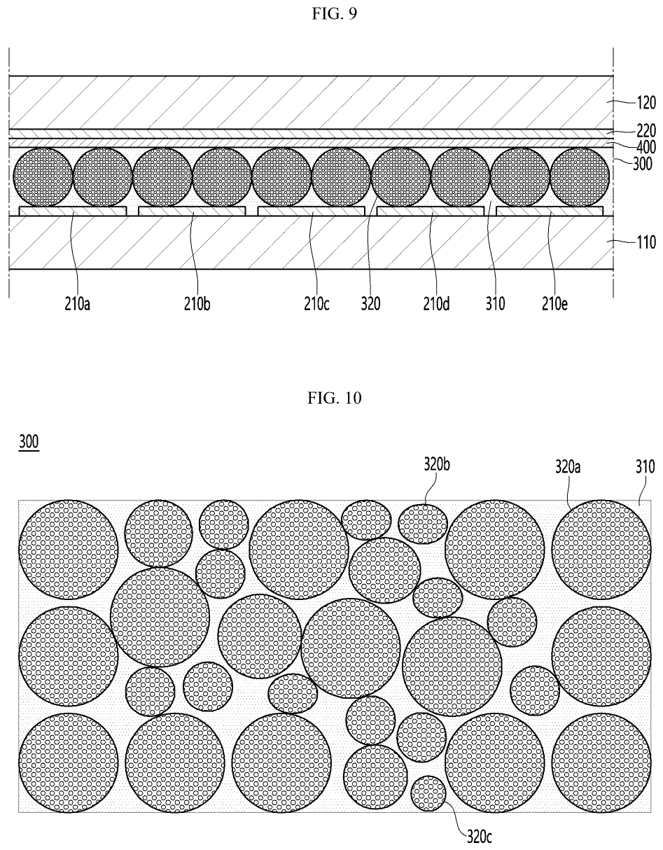

Referring to FIG. 9, the first electrode 210 includes a first-a electrode 210a, a first-b electrode 210b, a first-c electrode 210c, a first-d electrode 210d, and a first-e electrode 210e. That is, the first electrode 210 may include pattern electrodes of the first-a electrode 210a, the first-b electrode 210b, the first-c electrode 210c, the first-d electrode 210d, and the first-e electrode 210e.

The first-a electrode 210a, the first-b electrode 210b, the first-c electrode 210c, the first-d electrode 210d, and the first-e electrode 210e may be disposed spaced apart from each other.

As shown in FIG. 6 and FIG. 8, the first-a electrode 210a, the first-b electrode 210b, the first-c electrode 210c, the first-d electrode 210d, and the first-e electrode 210e may be formed with the same or similar sizes. Alternatively, as shown in FIG. 7, the first-a electrode 210a, the first-b electrode 210b, the first-c electrode 210c, the first-d electrode 210d, and the first-e electrode 210e may be formed with different sizes.

The first-a electrode 210, the first-b electrode 210b, the first-c electrode 210c, the first-d electrode 210d, and the first-e electrode 210e may be individually driven. For example, a voltage is applied to at least one of the first-a electrode 210a, the first-b electrode 210b, the first-c electrode 210c, the first-d electrode 210d, and the first-e electrode 210e, and no voltage is applied to at least another electrode of the electrodes.

For example, a voltage may be applied to the first-a electrode 210a, the first-c electrode 210c, and the first-e electrode 210e. In addition, a voltage may not be applied to the first-b electrode 210b and the first-d electrode 210d. Accordingly, the capsule part 320 disposed on the first-a electrode 210a, the first-c electrode 210c, and the first-e electrode 210e becomes a light transmitting part. In addition, the capsule part 320 disposed on the first-b electrode 210b and the first-d electrode 210d becomes a light blocking part.

Since the first electrode 210 is individually driven for each pattern electrode, the light transmission control member can transmit light in various ways. For example, one region of the light transmission control member is formed as a light blocking part. In addition, another region is formed as a light transmitting part. Alternatively, the light transmission control member may be formed with a light blocking part and a light transmitting part alternately. Alternatively, the light transmission control member may form a logo, a number, or a symbol.

An usability of the light transmission control member according to the embodiment may increase. In detail, at least one of the first electrode and the second electrode is formed as a pattern electrode. In addition, the pattern electrode is individually driven. Accordingly, light passing through the light transmission control member may be transmitted in various ways. Therefore, the light transmission control member is utilized in various ways.

FIG. 10 is another top view of a light conversion part of a light transmission control member according to an embodiment.

Referring to FIG. 10, the light conversion part 300 includes a plurality of capsule parts. The plurality of capsule parts have different sizes.

In detail, the capsule part includes a first capsule part 320a, a second capsule part 320b, and a third capsule part 320c. The first capsule part 320a, the second capsule part 320b, and the third capsule part 320c are formed with different sizes. For example, a size of the first capsule part 320a may be larger than a size of each of the second capsule part 320b and the third capsule part 320c. In addition, a size of the second capsule part 320b may be larger than a size of the third capsule part 320c.

Since the capsule part includes a plurality of capsule parts having different sizes, the light transmittance may be reduced when the light conversion part is driven as a light blocking part. As described in FIG. 4, when the light conversion part is driven as a light blocking part, light is not blocked between the capsule parts 320. Accordingly, light may be transmitted within a set range. Accordingly, even when driven as the light blocking part, light is transmitted, so the user's visibility may be reduced.

Accordingly, as shown in FIG. 10, the capsule parts are formed in different sizes. Accordingly, an area through which light is transmitted between the capsule parts is reduced. That is, an filling area in which the capsule part is disposed inside the receiving part 310 is increased. Accordingly, an area through which light is transmitted between the capsule parts is reduced.

Accordingly, when the light conversion part is driven as a light blocking part, the light transmittance is reduced. Accordingly, when a user uses the light transmission control member in a privacy mode or a light blocking mode, the light transmittance is reduced. Accordingly, the user can use the light transmission control member stably.

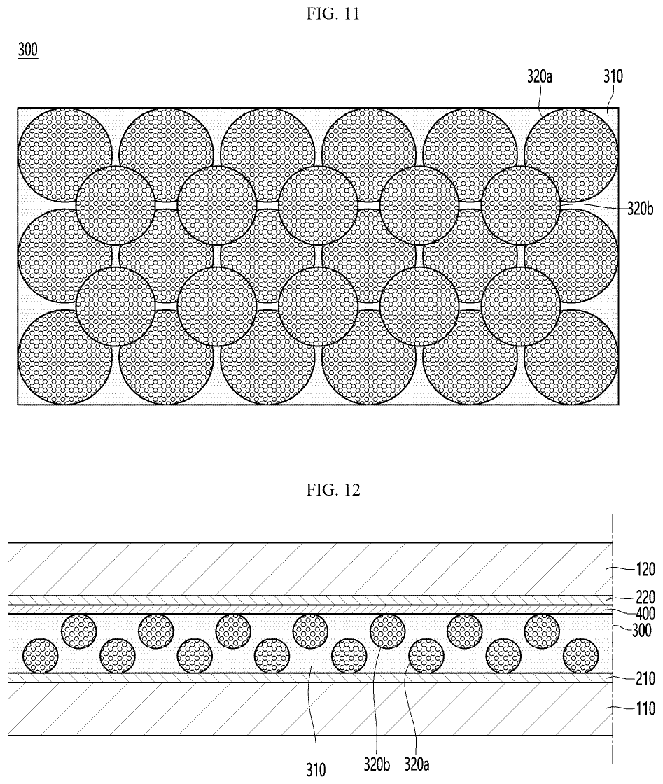

FIG. 11 is another top view of a light conversion part of a light transmission control member according to an embodiment, and FIG. 12 is another cross-sectional view of a light transmission control member according to an embodiment.

Referring to FIG. 11 and FIG. 12, the light conversion part 300 includes a plurality of capsule parts. The plurality of capsule part includes a first capsule part 320a and a second capsule part 320b. The first capsule part 320a and the second capsule part 320b may have a same size. Alternatively, the first capsule part 320a and the second capsule part 320b may have different sizes.

The second capsule part 320b is disposed on the first capsule part 320a. In detail, the first capsule part 320a is disposed at a lower side of the receiving part 310. In addition, the second capsule part 320b is disposed at an upper side of the receiving part 310. Accordingly, the second capsule part 320b is disposed on the first capsule part 320a inside the receiving part 310.

The capsule part includes a plurality of capsule parts disposed at different heights. Therefore, when the light conversion part is driven by a light blocking part, the light transmittance is reduced. As shown in FIG. 11, since the capsule parts are disposed at different heights, an area through which light is transmitted between the capsule parts is reduced. That is, an area inside the receiving part 310 where the capsule parts are not disposed is reduced. Therefore, an area through which light is transmitted between the capsule parts is reduced.

Accordingly, when the light conversion part is driven as a light blocking part, the light transmittance is reduced. Therefore, when a user uses the light transmission control member in privacy mode or light-blocking mode, the light transmittance is reduced. Therefore, a user can use the light transmission control member stably.

Meanwhile, FIG. 11 and FIG. 12 illustrate that the capsule part is disposed in two layers. However, the embodiment is not limited thereto. That is, the capsule part may further include a third capsule part on the second capsule part. That is, the capsule part may be disposed in three or more layers.

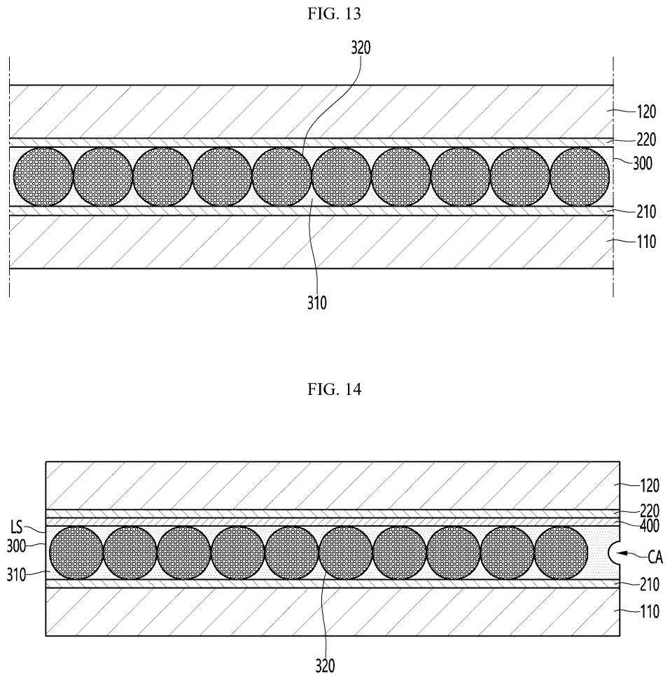

FIG. 13 is another cross-sectional view of a light transmission control member according to an embodiment.

Referring to FIG. 13, the light transmission control member may omit the adhesive layer 400. In detail, the light conversion part 300 is in direct contact with the second electrode 220.

For example, the receiving part 310 includes a binder. A plurality of capsule parts 320 may be dispersed inside the binder to form the light conversion part 300. Accordingly, the light conversion part 300 may have adhesive properties due to the binder.

Accordingly, the light conversion part 300 is adhered to the second electrode 220 without a separate adhesive layer. Therefore, a separate adhesive layer can be omitted. Thereby, a manufacturing process can be simplified. In addition, a thickness of the light transmission control member can be reduced.

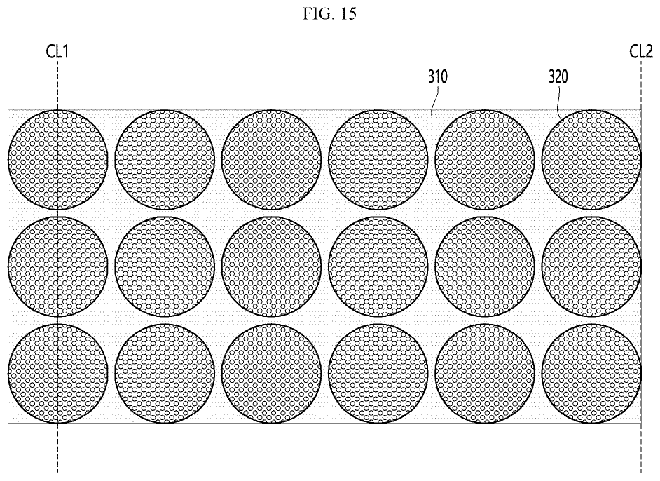

FIG. 14 is a cross-sectional view taken along region B-B′ of FIG. 1, and FIG. 15 is a drawing for explaining a cutting process of a light transmission control member according to an embodiment.

Referring to FIG. 1 and FIG. 14, the light transmission control member includes an outer surface LS. The light conversion part 300 is exposed on the outer surface LS. In detail, the light conversion part 300 is exposed on at least one of the plurality of outer surfaces LS. More specifically, the receiving part 310 is exposed on at least one of the plurality of outer surfaces LS.

At least one of the plurality of outer surfaces LS may include a convex region CA. In detail, at least one of the plurality of outer surfaces LS may include at least one convex region CA.

The convex region CA is formed during a manufacturing process of the light transmission control member. Referring to FIG. 15, one light transmission control member may be formed by cutting a first cutting line CL1 and a second cutting line CL2. At this time, the first cutting line CL1 may be a region overlapping the capsule part 320. Accordingly, in a region cut by the cutting line CL1, the capsule part 320 exits the receiving part 310. Accordingly, at least one outer surface may include at least one convex region formed by exiting the capsule part 320.

A light transmission control member according to the embodiment includes a first electrode. In addition, a plurality of capsule parts are disposed on one first electrode. Accordingly, a light transmittance of the light transmission control member changes on a front surface of the light transmission control member by a single voltage application.

Accordingly, an user can conveniently use the light transmission control member. In addition, a power consumption required to drive the light transmission control member is reduced.

In addition, the first electrode includes a plurality of pattern electrodes. In addition, a plurality of capsule parts are disposed on each pattern electrode.

In addition, the pattern electrodes are individually driven. Accordingly, the light transmittance of the light transmission control member changes in various ways depending on the individual driving method of the pattern electrodes.

Accordingly, the user can use the light transmission control member in various environments. In addition, the user can use the light transmission control member for various purposes. For example, the light transmission control member can be used for various purposes by displaying symbols, letters, numbers, etc. on the light transmission control member.

In addition, the capsule part includes a plurality of capsule parts of different sizes. Alternatively, the plurality of capsule parts are disposed in two or more layers. Accordingly, when the light transmission control member is used as a light blocking part, the light transmittance is reduced. Accordingly, the user's visibility is improved.

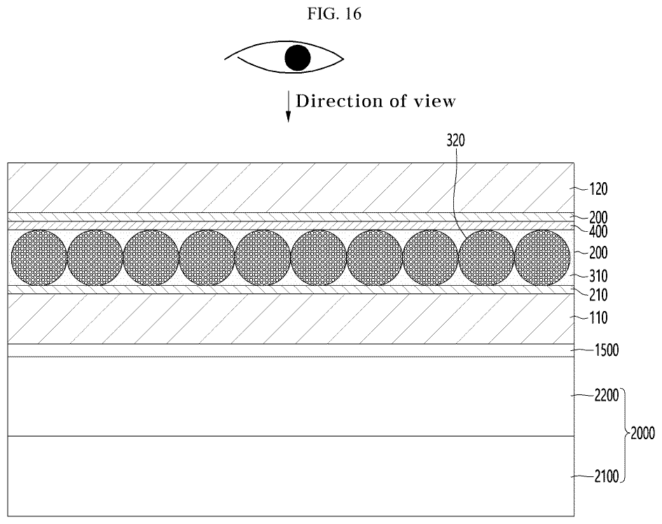

Hereinafter, a display device and a display device to which a light transmission control member according to an embodiment is applied will be described with reference to FIGS. 16 to 22.

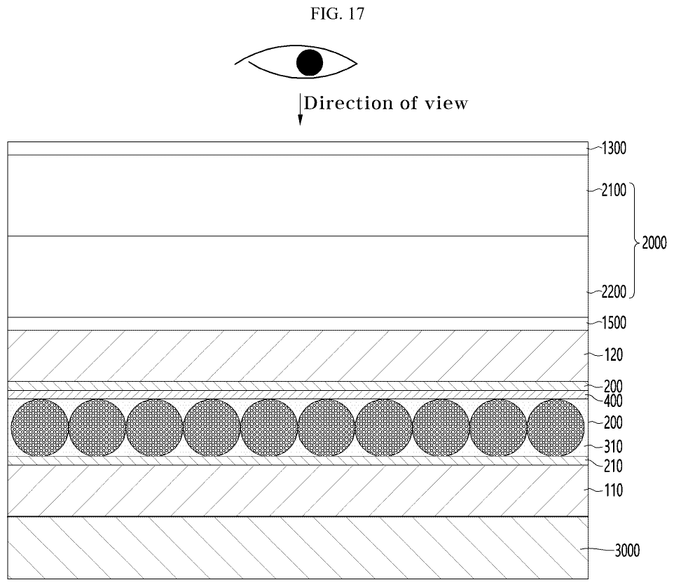

Referring to FIGS. 16 and 17, a light transmission control member 1000 according to an embodiment may be disposed on or under a display panel 2000.

The display panel 2000 and the light transmission control member 1000 may be adhered to each other. For example, the display panel 2000 and the light transmission control member 1000 may be adhered to each other by an adhesive member 1500. The adhesive member 1500 may be transparent. For example, the adhesive member 1500 may include an adhesive including an optically transparent adhesive material. In addition, the adhesive member 1500 may include a release film.

The display panel 2000 may include a first base substrate 2100 and a second base substrate 2200. The display panel 2000 may be formed with a structure in which a first base substrate 2100 including a thin film transistor (TFT) and a pixel electrode and a second base substrate 2200 including color filter layers are bonded with a liquid crystal layer therebetween.

In addition, the display panel 2000 may be a liquid crystal display panel having a color filter on transistor (COT) structure in which a thin film transistor, a color filter, and a black electrolyte are formed on the first base substrate 2100, and a second base substrate 2200 is bonded with the first base substrate 2100 with a liquid crystal layer therebetween. That is, a thin film transistor can be formed on the first base substrate 2100, a protective film can be formed on the thin film transistor, and a color filter layer can be formed on the protective film. In addition, a pixel electrode in contact with the thin film transistor can be formed on the first base substrate 2100. At this time, in order to improve an aperture ratio and simplify a mask process, a black electrolyte can be omitted, and a common electrode can also be formed to function as a black electrolyte.

As shown in FIG. 16, when the display panel 2000 is an organic light-emitting display panel, the light transmission control member may be formed on an upper portion of the organic light-emitting display panel. That is, when a surface of the organic light-emitting display panel that an user views is defined as an upper portion of the organic light-emitting display panel, the light transmission control member may be disposed on the upper portion of the organic light-emitting display panel. The display panel 2000 may include a self-luminous element that does not require a separate light source. The display panel 2000 may include a thin film transistor formed on a first base substrate 2100, and an organic light-emitting element in contact with the thin film transistor. The organic light-emitting element may include an anode, a cathode, and an organic light-emitting layer formed between the anode and the cathode. In addition, the organic light-emitting element may further include a second base substrate 2200 that serves as a sealing substrate for encapsulation on the organic light-emitting element.

Alternatively, when the display panel 2000 is a liquid crystal display panel, the light transmission control member may be formed on a lower portion of the liquid crystal panel. That is, when the surface of the liquid crystal panel that the user views is defined as an upper portion of the liquid crystal panel, the light transmission control member may be disposed on a lower portion of the liquid crystal panel. That is, as shown in FIG. 17, the light transmission control member may be disposed on a lower portion of the liquid crystal panel and an upper portion of the backlight unit 3000, so that the light transmission control member may be disposed between the backlight unit 3000 and the display panel 2000.

In addition, although not shown in the drawing, a polarizing plate may be further disposed between the light transmission member 1000 and the display panel 2000. The polarizing plate may be a linear polarizing plate or an external light reflection prevention polarizing plate. For example, if the display panel 2000 is a liquid crystal display panel, the polarizing plate may be a linear polarizing plate. In addition, if the display panel 2000 is an organic light-emitting diode panel, the polarizing plate may be a polarizing plate for preventing reflection of external light.

In addition, an additional functional layer 1300, such as an anti-reflection layer or an anti-glare layer, may be further disposed on the light transmission control member 1000. In detail, the functional layer 1300 may be adhered to one side of the first substrate 110 of the light transmission control member. Although not shown in the drawing, the functional layer 1300 may be adhered to the second substrate 120 of the light transmission control member through an adhesive layer. In addition, a release film protecting the functional layer may be further disposed on the functional layer 1300.

In addition, a touch panel may be further disposed between the display panel and the light transmission control member.

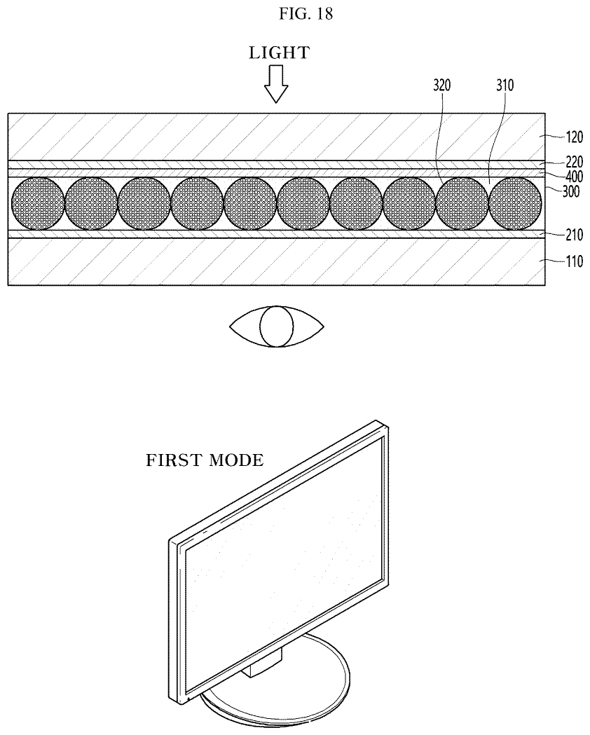

Referring to FIGS. 18 to 22, the light transmission control member according to the embodiment may be applied to various display devices.

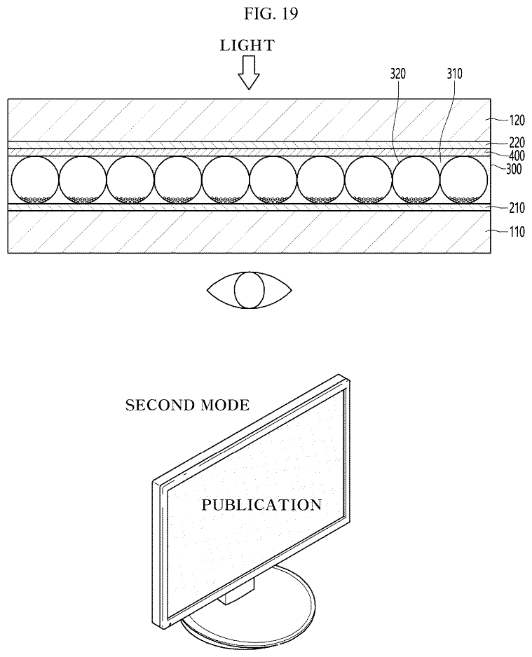

Referring to FIGS. 18 and 19, the light transmission control member according to the embodiment can be applied to a display device that displays a display.

For example, as in FIG. 18, when a voltage is not applied to the light transmission control member, the light conversion part is driven as a light blocking part. Accordingly, the display device is driven in the first mode. In addition, as in FIG. 19, when a voltage is applied to the light transmission control member, the light conversion part is driven as a light transmitting part. Accordingly, the display device is driven in the second mode.

Accordingly, the user can drive the display device in a privacy mode or a light blocking mode depending on an application of the voltage.

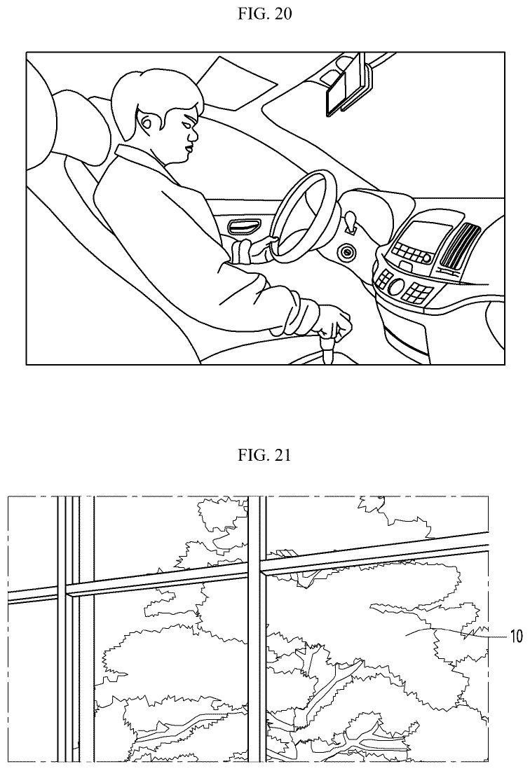

In addition, referring to FIGS. 20 to 22, the light transmission control member according to the embodiment can be applied to an interior and exterior of a vehicle and windows of a building.

For example, as in FIG. 20, the light transmission control member according to the embodiment may display a video confirming information of the vehicle and a movement route of the vehicle. The display device may be disposed between a driver seat and a passenger seat of the vehicle.

In addition, the light transmission control member according to the embodiment may be applied to a dashboard that displays a speed, an engine, an alarm signal, and the like of the vehicle.

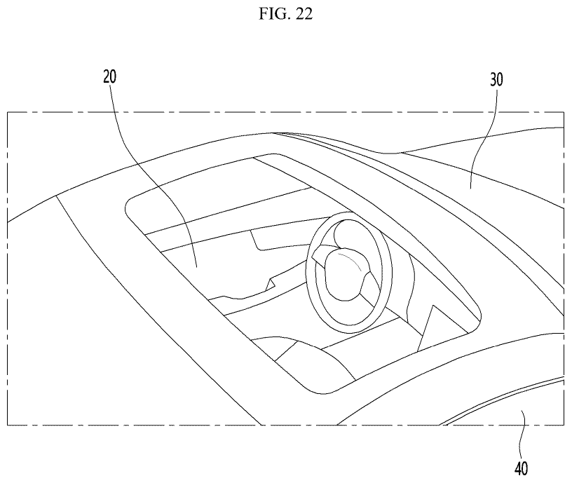

In addition, as shown in FIG. 21, the light transmission control member according to the embodiment can be applied to a window 10 of a building. Accordingly, an amount of light passing through the window 10 can be controlled.

In addition, as shown in FIG. 22, the light transmission control member according to the embodiment can be applied to a sunroof 20, a front glass 30 or right and left window glasses 40 of the vehicle.

The characteristics, structures, effects, and the like described in the above-described embodiments are included in at least one embodiment of the present invention, but are not limited to only one embodiment. Furthermore, the characteristic, structure, and effect illustrated in each embodiment may be combined or modified for other embodiments by a person skilled in the art. Accordingly, it is to be understood that such combination and modification are included in the scope of the present invention.

In addition, embodiments are mostly described above, but the embodiments are merely examples and do not limit the present invention, and a person skilled in the art may appreciate that several variations and applications not presented above may be made without departing from the essential characteristic of embodiments. For example, each component specifically represented in the embodiments may be varied. In addition, it should be construed that differences related to such a variation and such an application are included in the scope of the present invention defined in the following claims.

1. A light transmission control member comprising:
a first substrate;
a first electrode disposed on the first substrate;
a light conversion part disposed on the first electrode;
a second electrode disposed on the light conversion part; and
a second substrate disposed on the second electrode;
wherein the light conversion part includes a capsule part,
wherein the capsule part includes a plurality of light conversion particles that moves according to a voltage applied to at least one of the first electrode and the second electrode, and
wherein the plurality of light conversion particles move in a same direction toward the first electrode or the second electrode according to the applied voltage.

2. The light transmission control member of claim 1, wherein the capsule part comprises a plurality of capsules, and
wherein 100 or more capsules are disposed on the first electrode.

3. The light transmission control member of claim 1, wherein the capsule part includes a dispersion in which the light conversion particles are dispersed, and
wherein the plurality of light conversion particles move in a direction toward the first electrode within the dispersion according to the applied voltage.

4. The light transmission control member of claim 1, wherein at least one of the first electrode and the second electrode includes a plurality of pattern electrodes disposed spaced apart from each other.

5. The light transmission control member of claim 4, wherein the plurality of pattern electrodes have different widths in a horizontal direction.

6. The light transmission control member of claim 4, wherein the plurality of capsules are disposed on the plurality of pattern electrodes.

7. The light transmission control member of claim 4, wherein the plurality of pattern electrodes include a first pattern electrode and a second pattern electrode spaced apart along a horizontal direction, and
wherein different voltages are applied to the first pattern electrode and the second pattern electrode.

8. The light transmission control member of claim 7, wherein the capsule part includes a
plurality of first capsules disposed on the first pattern electrode, and a plurality of second capsules disposed on the second pattern electrode, and
wherein the plurality of first capsules and the plurality of second capsules are individually driven.

9. The light transmission control member of claim 8, wherein
a number of the plurality of first capsules and a number of the plurality of second capsules are different from each other.

10. The light transmission control member of claim 6, wherein the plurality of capsules have different sizes.

11. The light transmission control member of claim 6, wherein the capsule part includes a plurality of first capsules disposed on the first electrode; and a plurality of second capsules disposed on the plurality of first capsules.

12. The light transmission control member of claim 11, wherein a size of at least one first capsule among the plurality of first capsules is different from a size of at least one second capsule among the plurality of second capsules.

13. The light transmission control member of claim 12, wherein the size of at least one first capsule is larger than the size of at least one second capsule.

14. The light transmission control member of claim 11, wherein the plurality of first capsules and the plurality of second capsules are disposed alternately along a horizontal direction.

15. The light transmission control member of claim 1, wherein an outer surface of the receiving part includes at least one concave portion concave toward the capsule part.

16. The light transmission control member of claim 15, wherein a size of the concave portion corresponds to a size of the capsule part.

17. The light transmission control member of claim 16, wherein a curvature of the concave portion corresponds to a curvature of the capsule part.
